(19) United States
(12) Patent Application Publication
(10) Pub. No.: US 2026/0032822 A1
(43) Pub. Date: Jan. 29, 2026

(54) ELECTRONIC MODULE

(71) Applicant: CANON KABUSHIKI KAISHA, Tokyo (JP)

(72) Inventor: NOBUAKI YAMASHITA, Kanagawa (JP)

(21) Appl. No.: 19/272,746

(22) Filed: Jul. 17, 2025

(30) Foreign Application Priority Data
Jul. 23, 2024 (JP) 2024-117857

(51) Int. Cl. H05K 1/18; H05K 1/11

(52) U.S. Cl. CPC H05K 1/181; H05K 1/111; H05K 2201/10015; H05K 2201/10522; H05K 2201/1053; H05K 2201/10545; H05K 2201/10628; H05K 2201/10636

(57) ABSTRACT

An electronic module includes: a printed wiring board; a semiconductor component mounted on the printed wiring board and having a first lead and a second lead soldered to the printed wiring board, respectively; and a chip component, wherein the chip component is arranged between the printed wiring board and at least one of the first lead and the second lead, and wherein a portion of a package body of the semiconductor component is lower than a height of the chip component.

### BACKGROUND

### Field of the Technology

The present disclosure relates to an electronic module.

### Description of the Related Art

In recent years, the malfunctions of semiconductor apparatuses have tended to increase as circuit operations have become faster and power supply voltages have been lowered. The causes of malfunctions of the semiconductor apparatuses are that the power supply potential of the semiconductor apparatus varies due to external noise propagating through the power supply wiring of the printed circuit board and so-called self-noise caused by the operation of the semiconductor apparatus itself. Manufacturers of semiconductor apparatuses recommend measures to place a capacitor in the vicinity of the power supply terminal of the semiconductor apparatus in order to suppress fluctuations in the power supply potential caused by these noises. For example, in order to suppress increases in the power supply impedance, a method to avoid malfunction is used by adding a capacitor.

Japanese Patent Laid-Open No. 2012-109411 discloses that elements are arranged around a semiconductor apparatus provided with leads.

In the vicinity of a semiconductor apparatus, a large number of wirings and electrical components for input and output of signals with other surrounding components and for power supply are densely arranged, and the space for arranging the capacitor is small. Adding a capacitor at a position away from the semiconductor apparatus not only leads to enlargement of the printed circuit board, but also reduces the effect of reducing the power supply impedance.

Thus, it is required to ensure the functionality for reducing the power supply impedance and suppressing the radiation or intrusion of noise. It is also required to suppress the enlargement of the printed circuit board. It is necessary to improve mounting technology effective for miniaturization of printed circuit boards and improvement of functionality.

### SUMMARY

The present disclosure is directed to provide an advantageous technology for achieving an improved mounting structure in an electronic module.

According to one aspect of the present disclosure, there is provided an electronic module including: a printed wiring board; a semiconductor component mounted on the printed wiring board and having a first lead and a second lead soldered to the printed wiring board, respectively; and a chip component, wherein the chip component is arranged between the printed wiring board and at least one of the first lead and the second lead, and wherein a portion of a package body of the semiconductor component is lower than a height of the chip component.

Features of the present disclosure will become apparent from the following description of embodiments with reference to the attached drawings. The following description of embodiments is described by way of example.

### BRIEF DESCRIPTION OF THE DRAWINGS

FIG. 1A is a front view illustrating an example of electronic equipment according to a first embodiment.

FIG. 1B is a side view illustrating the example of the electronic equipment according to the first embodiment.

FIG. 2 is a schematic diagram illustrating an electronic module according to the first embodiment.

FIG. 3A is a perspective view illustrating the electronic module according to the first embodiment.

FIG. 3B is a cross-sectional view illustrating the electronic module according to the first embodiment.

FIG. 3C is a plan view of the first main surface and the second main surface of the electronic module according to the first embodiment, viewed from the top.

FIG. 4A is a graph showing the relationship between the frequency and the power supply impedance of the electronic module according to the first embodiment and the comparative configuration.

FIG. 4B is a cross-sectional view illustrating the mounting position of a chip component in the electronic module according to the first embodiment.

FIG. 4C is a view illustrating an equivalent circuit of the electronic module according to the first embodiment.

FIG. 5A is a perspective view illustrating an electronic module according to a third embodiment.

FIG. 5B is a cross-sectional view illustrating the electronic module according to the third embodiment.

FIG. 5C is a plan view of the first main surface of the electronic module according to the third embodiment, viewed from the top.

FIG. 6 is a graph showing the relationships between the frequency and the power supply impedance of the electronic modules according to a comparative example and a second embodiment and the third embodiment.

FIG. 7A is a perspective view illustrating an electronic module according to a fourth embodiment.

FIG. 7B is a plan view of the first main surface of the electronic module according to the fourth embodiment, viewed from the top.

FIG. 7C is a graph showing the relationship between the frequency and the power supply impedance of the electronic module according to the fourth embodiment.

FIG. 8A is a perspective view illustrating an electronic module according to a fifth embodiment.

FIG. 8B is a plan view of the first main surface of the electronic module according to the fifth embodiment, viewed from the top.

FIG. 9 is a perspective view illustrating an electronic module according to another embodiment.

FIG. 10 is a perspective view illustrating an electronic module according to another embodiment.

FIG. 11 is a perspective view illustrating an electronic module according to another embodiment.

FIG. 12 is a perspective view illustrating an electronic module according to another embodiment.

FIG. 13 is a perspective view illustrating an electronic module according to another embodiment.

FIG. 14 is a perspective view illustrating an electronic module according to another embodiment.

FIG. 15A is a perspective view illustrating an electronic module according to a comparative configuration.

FIG. 15B is a cross-sectional view illustrating the electronic module according to the comparative configuration.

FIG. 15C is a plan view of the first main surface of an electronic module according to the comparative configuration, viewed from the top.

FIG. 15D is a plan view of the second main surface of the electronic module according to the comparative configuration.

FIG. 15E is a plan view of a wiring structure example on the first main surface of the electronic module according to the comparative configuration, viewed from the top.

### DESCRIPTION OF THE EMBODIMENTS

Hereinafter, embodiments of the present disclosure will be described in detail with reference to the drawings. However, the following embodiments are some embodiments of the present disclosure, and the present disclosure is not limited thereto. A common configuration will be described by referring to a plurality of drawings, and a configuration with common reference numerals will be omitted.

### First Embodiment

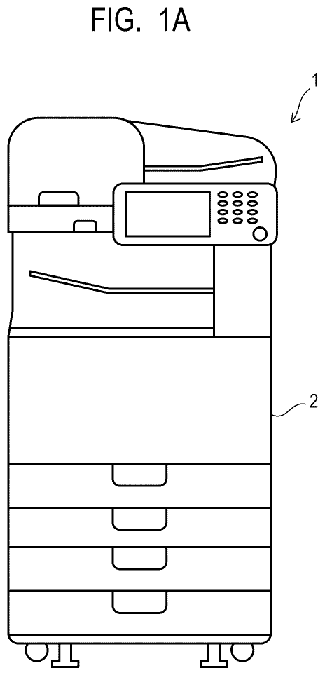

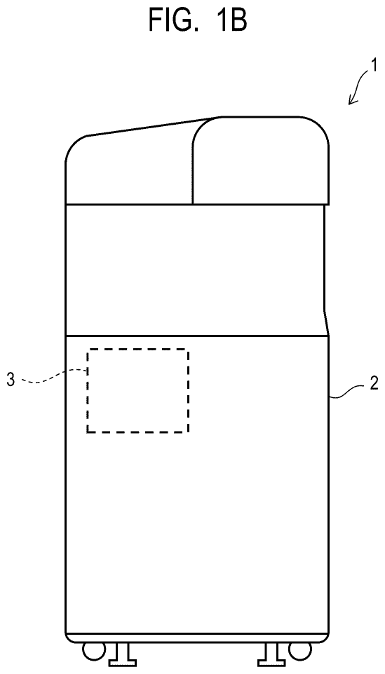

Electronic equipment and an electronic module according to a first embodiment of the present disclosure will be described with reference to FIG. 1A to FIG. 4C. Note that, in the present embodiment, electronic equipment (printing equipment) equipped with an image forming apparatus will be described as an example of the electronic equipment. However, the electronic equipment to which the present disclosure applies may include not only printing equipment but also imaging equipment such as cameras and the like, medical equipment such as CT, MRI, and the like, industrial equipment such as robots, electronic component manufacturing apparatuses, and the like, and transportation equipment such as automobiles, aircrafts, ships, and the like.

FIG. 1A is a front view illustrating the electronic equipment 1 according to the present embodiment. FIG. 1B is a side view illustrating the electronic equipment according to the present embodiment. The electronic equipment 1 is electrophotographic printing equipment such as a printer, a copier, a FAX, a multifunction printer, or the like, but may be inkjet printing equipment.

As illustrated in FIG. 1A and FIG. 1B, the electronic equipment 1 includes an image forming apparatus 2 that forms an image on a sheet, and an electronic module 3 that controls the image forming apparatus 2. The electronic module 3 that controls the image forming apparatus 2 can be referred to as a control module. The electronic equipment 1 includes a housing. The electronic module 3 is arranged inside the housing of the electronic equipment 1. The image forming apparatus 2 is also arranged inside the housing of the electronic equipment 1. The image forming apparatus 2 includes an image forming unit that forms an image on a sheet and a transport mechanism that transports the sheet. The image forming unit includes a photosensitive drum (not illustrated), a charging unit, a developing unit, a transfer unit, a fixing unit, and the like, which are elements necessary for forming an image on a sheet.

The electronic module 3 is an electronic module configured as a printed circuit board. The electronic module 3 receives image data from external equipment via an interface such as a LAN (Local Area Network), a USB (Universal Serial Bus), or the like. The electronic module 3 processes the received image data, transmits the image data to the image forming apparatus 2, and controls the image forming apparatus 2 so as to form an image on a sheet.

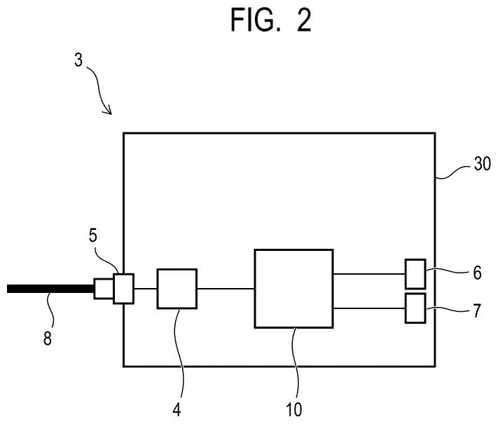

FIG. 2 is a schematic diagram illustrating the electronic module 3 according to the present embodiment. As illustrated in FIG. 2, the electronic module 3 includes an integrated circuit device 4 as an example of a semiconductor component and an integrated circuit device 10 as an example of a semiconductor component. The electronic module 3 also includes connectors 5, 6 and 7, and a printed wiring board 30. In the electronic module 3 configured as a printed circuit board, the integrated circuit device 4, the connectors 5, 6, and 7, and the integrated circuit device 10 are mounted on the printed circuit board 30. The printed circuit board 30 is, for example, a rigid board.

A communication cable 8 such as a LAN (Local Area Network) cable or the like is attached to the connector 5, and image data are received from the external equipment via the communication cable 8. The integrated circuit device 4 processes the image data received at the connector 5, stores the image data in a memory controller and a memory device (not illustrated), reads the image data from the memory device, and outputs the image data to the integrated circuit device 10. The integrated circuit device 10 outputs the image data to the connectors 6 and 7, and transmits the image data to an image forming unit connected to the connectors 6 and 7 by communication cables (not illustrated). In the electronic module 3 of this example, the integrated circuit device 4 is used as a conversion chip and the integrated circuit device 10 is used as a communication device, but the electronic module 3 to which the present disclosure is applicable is not limited thereto.

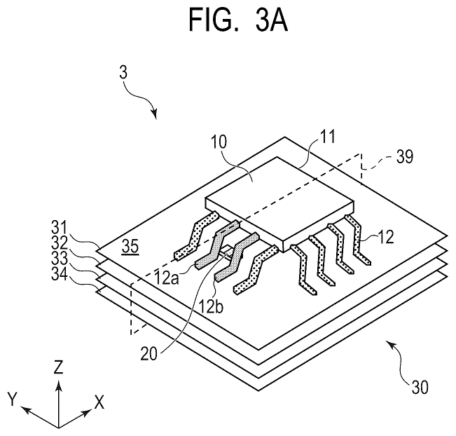

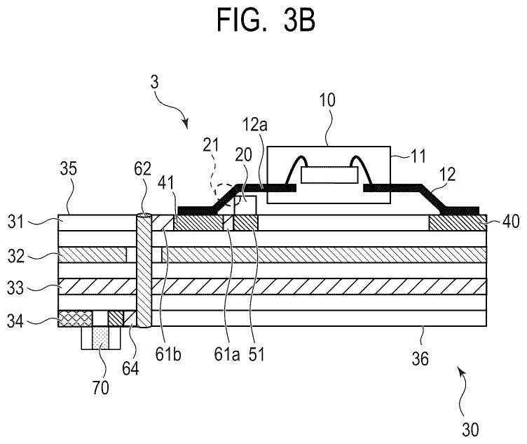

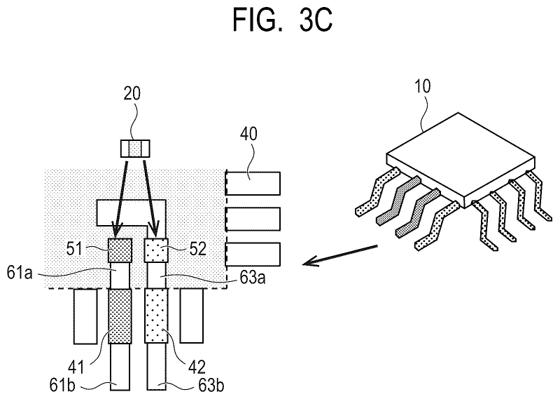

FIG. 3A is a perspective view illustrating the printed wiring board 30 constituting the electronic module 3 according to the present embodiment. FIG. 3A illustrates a portion of the printed wiring board 30 where the integrated circuit device 10 is mounted. Note that, in the following description, directions orthogonal to each other along the first main surface 35 of the printed circuit board 30 on which the integrated circuit device 10 is mounted are an X direction and a Y direction, and a direction perpendicular to the first main surface 35 is a Z direction.

As illustrated in FIG. 3A, the integrated circuit device 10 is a semiconductor component, has a package structure of, for example, a Quad Flat Package (QFP), and includes a package body 11 and a plurality of leads 12. The present embodiment is preferred when the integrated circuit device has 8 or more leads, and is also preferred when the integrated circuit device 10 has 16 or more leads, wherein the plurality of leads 12 include leads 12a and 12b, are outer leads constituting the lead frame, and project from the side surfaces of the package body 11 on four sides along the X and Y directions. The electronic module 3 further includes a chip component 20. The integrated circuit device 10 and the chip component 20 are mounted on the first main surface 35 of the printed wiring board 30. The chip component 20 is mounted between the leads 12a and 12b of the integrated circuit device 10 and the first main surface 35 of the printed wiring board 30. That is, the chip component 20 is arranged between portions of the leads 12a and 12b away from the printed wiring board 30 and the printed wiring board 30. The chip component 20 is a capacitor component such as a multilayer ceramic capacitor or the like.

The printed circuit board 30 is a substrate wherein wirings that electrically connect components mounted on the printed circuit board 30 such as the integrated circuit device 10 are formed on the surface and inside. Note that, in place of the printed circuit board 30, a substrate which can provide an electrical connection to the mounted components such as the integrated circuit device 10 and the like can be used.

FIG. 3B is a cross-sectional view illustrating a cross section along the X direction illustrated in the region 39 in FIG. 3A. The cross section illustrated in FIG. 3B includes the lead 12a as a power supply lead which is one of the leads 12 along the X direction to which a power supply potential to be supplied to the integrated circuit device 10 is supplied in the electronic module 3 according to the present embodiment.

The printed wiring board 30 includes an insulating base material and a conductive conductor constituting the wirings. The material of the base material is, for example, epoxy resin. The material of the conductor is, for example, copper. As illustrated in FIG. 3B, the printed wiring board 30 is, for example, a four-layer laminated substrate that includes four conductor layers 31, 32, 33, and 34. The conductor layers 31, 32, 33, and 34 are spaced apart from each other in the Z direction perpendicular to the first main surface 35. The base material, that is, an insulating layer, is provided between the conductor layer 31 and the conductor layer 32, between the conductor layer 32 and the conductor layer 33, and between the conductor layer 33 and the conductor layer 34, respectively. The conductor layers 31, 32, 33, and 34 are arranged so that the conductor layers 31, 32, 33, and 34 are stacked in the order of the conductor layer 31, the conductor layer 32, the conductor layer 33 and the conductor layer 34 from the first main surface 35 to the second main surface 36 with the insulating layers therebetween.

The conductor layer 31 is a first surface layer having the first main surface 35 which is a mounting surface on which integrated circuit device 10, the chip component 20, and the like are mounted. The conductor layer 34 is a second surface layer having the second main surface 36 which is a main surface opposite to one main surface. The conductor layer 32 located between the conductor layer 31 and the conductor layer 34 is a first inner layer, and the conductor layer 33 located between the conductor layer 32 and the conductor layer 34 is a second inner layer.

A solder resist (not illustrated) may be arranged on the conductor layers 31 and 34. The conductor layers 31, 32, 33, and 34 are respectively provided with conductor patterns constituting wirings. The printed wiring board 30 is provided with a through via 62 which is a through hole constituting a wiring from the conductor layer 31 to the conductor layer 34.

Component pads 41 and 51 and wirings 61a and 61b are formed in the conductor layer 31. The lead 12a, which is one of the leads 12 of the integrated circuit device 10, is soldered and joined to the component pad 41. One of the terminals of the chip component 20 is soldered and joined to the component pad 51. The component pad 41 and the component pad 51 are connected by wiring 61a. Wiring 61b is connected to the component pad 41. Thus, one of the terminals of the chip component 20 connected to the component pad 51 is electrically connected to the lead 12a connected to the component pad 41.

The chip component 20 is arranged between the package body 11 of the integrated circuit device 10, the lead 12a, and the conductor layer 31 of the printed circuit board 30. The chip component 20 may be arranged between the printed wiring board 30 and at least one of the leads 12a and 12b. The chip component 20 is arranged so as not to overlap the package body 11 in a direction perpendicular to the main surface of the printed wiring board 30. By ensuring that the chip component 20 does not overlap the package body 11, it is possible to avoid making the mounting process difficult (making productivity (implementation speed) lower and making yield lower) and/or avoid making the inspection process difficult by visual observation or image processing. The wirings 61a and 61b are power supply wirings that supply power supply potential to the integrated circuit device 10. The wiring 61b is connected to the through via 62. A chip component 70 is mounted on the second main surface 36 of the conductor layer 34. A wiring 64 is provided on the conductor layer 34. The wiring 64 is connected to the chip component 70. The wiring 61b is connected to the chip component 70 via the through via 62 and wiring 64, and is also electrically connected to a power supply circuit (not illustrated).

Note that a part of the package body 11 may be located at a position lower than the height of the chip component 20. Even in this case, a space for mounting the chip component 20 can be secured between the first main surface 35 of the printed wiring board 30 and the lead 12.

FIG. 3C is a plan view of the first main surface 35 of the conductor layer 31 of the printed wiring board 30 viewed from the top in the Z direction. As illustrated in FIG. 3C, Component pads 40, 41, and 42 are formed in the conductor layer 31. The component pads 40, 41 and 42 are arrayed around the integrated circuit device 10 so as to correspond to a plurality of leads 12.

The plurality of leads 12 of the integrated circuit device 10 are soldered and joined to the component pads 40, 41 and 42. The lead 12a, which is one of the leads 12 supplied with a power supply potential to be supplied to the integrated circuit device 10, is soldered and joined to the component pad 41. The lead 12b, which is one of the leads 12 supplied with a ground potential to be supplied to the integrated circuit device 10, is soldered and joined to the component pad 42. The component pad 41 and the component pad 42 are arranged adjacent to each other. The component pad 41 is supplied with the power supply potential. The component pad 42 is supplied with the ground potential.

Component pads 51 and 52, the wirings 61a and 61b, and wirings 63a and 63b are formed in the conductor layer 31. The wirings 61a and 61b are power supply wirings. The wirings 63a and 63b are ground wirings.

The chip component 20 has two terminals, one of which is soldered and joined to the component pad 51, and the other of which is soldered and joined to the component pad 52. The component pad 41 that supplies a power supply potential is connected to the component pad 51 via the wiring 61a which is a power supply wiring. Further, the component pad 41 is electrically connected to a power supply circuit (not illustrated) via the power supply wiring 61b that is connected to the component pad 41. One terminal of the chip component 20 is electrically connected to the lead 12a via the component pad 51, the wiring 61a, and the component pad 41. The component pad 42 that supplies the ground potential is electrically connected to the component pad 52 via the wiring 63a, which is a ground wiring. Further, the component pad 42 is electrically connected to the power supply circuit (not illustrated) via the wiring 63b, which is a power supply wiring connected to the component pad 42. The other terminal of the chip component 20 is electrically connected to the lead 12b via the component pad 52, the wiring 63a, and the component pad 42.

Thus, in the electronic module 3 according to the present embodiment, the chip component 20 is mounted between the first main surface 35 of the printed wiring board 30 and the leads 12a and 12b. In the present embodiment, the chip component 20 can reduce the power supply impedance as described in detail below. Further, since the chip component 20 is mounted between the first main surface 35 of the printed circuit board 30 and the leads 12, the miniaturization of the electronic module 3 is not prevented by the chip component 20.

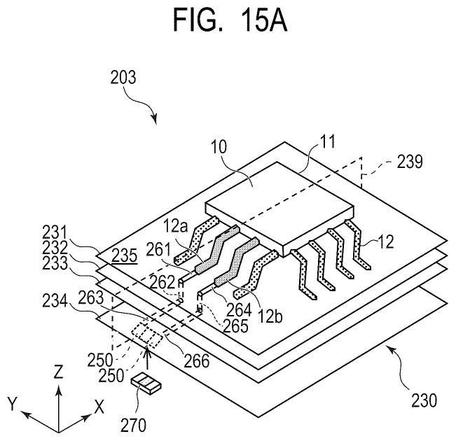

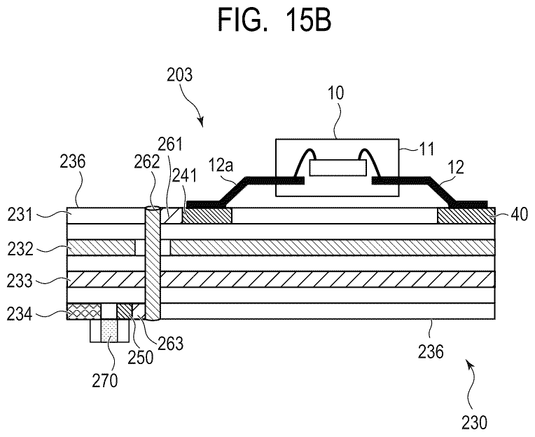

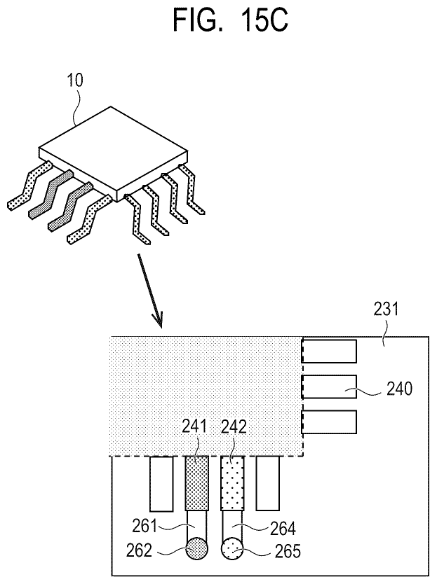

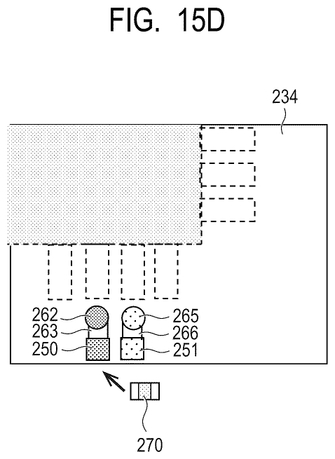

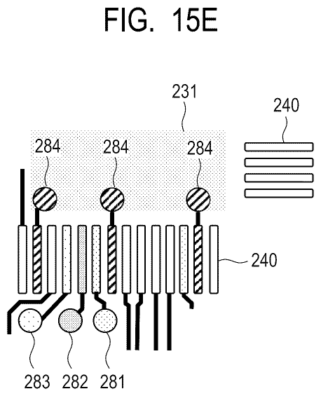

Hereinafter, details of the electronic module 3 according to the present embodiment will be described with reference to a comparative configuration illustrated in FIG. 15A to FIG. 15E. The comparative configuration illustrated in FIG. 15A to FIG. 15E differs from the configuration of the present embodiment illustrated in FIG. 3A to FIG. 3C in that the chip component 20 is not mounted. Note that, in FIG. 15A to FIG. 15E, the elements common to the present embodiment illustrated in FIG. 3A to FIG. 3C will be abbreviated or simplified by adding reference numerals common to the reference numerals in the present embodiment or reference numerals with 200 added to the reference numerals in the present embodiment.

FIG. 15A is a perspective view illustrating the printed circuit board 230 in the comparative configuration. As illustrated in FIG. 15A, the integrated circuit device 10 is mounted on the first main surface 235 of a conductor layer 231 of a printed circuit board 230. A chip component 270 is mounted on the second main surface 236 of a conductor layer 234 of the printed circuit board 230.

The plurality of leads 12 include the leads 12a and 12b. The lead 12a is a power supply lead that is one of the leads 12 to which a power supply potential is supplied. The power supply potential is supplied to the integrated circuit device 10. The lead 12a is connected to one terminal of the chip component 270 via a wiring 261 formed in the conductor layer 231, a through via 262, and a wiring 263 formed in the conductor layer 234. The wirings 261 and 263 are power supply wirings. The lead 12b is a ground lead that is one of the leads 12 to which a ground potential is supplied. The ground potential is supplied to the integrated circuit device 10. The lead 12b is connected to the other terminal of the chip component 270 via a wiring 264 formed in the conductor layer 231, a through via 265, and a wiring 266 formed in the conductor layer 234. The wirings 264 and 266 are ground wiring.

FIG. 15B is a cross-sectional view illustrating a cross section along the X direction illustrated in the region 239 in FIG. 15A. The cross section illustrated in FIG. 15B includes the lead 12a, which is one of the leads 12 supplied with the power supply potential to be supplied to the integrated circuit device 10 in the electronic module 203. A ground wiring that supplies the ground potential is formed in the conductor layer 232, which is the first inner layer of the printed circuit board 230. A power supply wiring that supplies the power supply potential is formed in the conductor layer 233, which is the second inner layer of the printed circuit board 230. The ground wiring and the power supply wiring are electrically connected to the power supply circuit (not illustrated). The chip component 270 is a capacitor component such as a multilayer ceramic capacitor or the like.

FIG. 15C is a plan view of the conductor layer 231 having the first main surface 235 of the printed wiring board 230, viewed from the top. FIG. 15D is a plan view of the conductor layer 234 having the second main surface 236 of the printed wiring board 230, viewed from the top. FIG. 15C and FIG. 15D are both views of the integrated circuit device 10, viewed from above the integrated circuit device 10 in the Z direction. The plurality of leads 12 of the integrated circuit device 10 are soldered and joined to component pads 240, 241, and 242 formed in the conductor layer 231. The lead 12a to which the power supply potential is supplied is soldered and joined to the component pad 241. The lead 12b to which the ground potential to be supplied to the integrated circuit device 10 is supplied is soldered and joined to the component pad 242. The component pad 241 is connected to the through via 262 via the wiring 261. The component pad 242 is connected to the through via 265 via the wiring 264. The through via 262 is connected to a component pad 250 formed in the conductor layer 234 via the wiring 263 formed in the conductor layer 234. The through via 265 is connected to a component pad 251 formed in the conductor layer 234 via the wiring 266 formed in the conductor layer 234.

FIG. 15E is a plan view illustrating an example of a wiring structure near the component pads 240 for mounting the integrated circuit device 10 in the printed circuit board 230 according to the comparative configuration. In FIG. 15E, a region of the conductor layer 231 in which the integrated circuit device 10 is mounted is viewed from the Z direction.

As illustrated in FIG. 15E, in the comparative configuration, in the conductor layer 231, a number of wirings and a number of through vias are provided near or around the component pads 240 connected to the integrated circuit device 10. The number of through vias includes through vias 281, 282, 283, and 284. The through vias 281, 282, and 283 are connected to the component pads 240 including the component pads 241 and 242, and are provided to provide different power supply potentials to the integrated circuit device 10. Through vias 284 are provided to provide ground potentials to the integrated circuit device 10. In this way, the conductor layer 231 near or around the component pads 240 has a high wiring density and cannot accommodate capacitor components for suppressing fluctuations in respective power supply potentials. Therefore, in the comparative configuration illustrated in FIG. 15A to FIG. 15E, the component pads that supply the power supply potentials and the ground potentials are connected to the chip components 270 mounted on the conductor layer 234 via the through vias 281, 282, 283, and 284. The chip component 270 is a capacitor component such as a multilayer ceramic capacitor.

As illustrated in FIG. 15A to FIG. 15E, a path for supplying the power supply potential to the integrated circuit device 10 includes the lead 12a, the wiring 261, the through via 262, and the wiring 263. A path for supplying the ground potential to the integrated circuit device 10 includes the lead 12b, the wiring 264, the through via 265, and the wiring 266. Thin and long leads, thin wirings of the substrate, and through vias exist in the paths for connecting the integrated circuit device 10 to the chip component 270 which is a capacitor component. Therefore, the power supply impedance especially in the high frequency band increases due to the inductance component parasitic on each of the elements that make up the paths, resulting in increased fluctuation in the power supply potential.

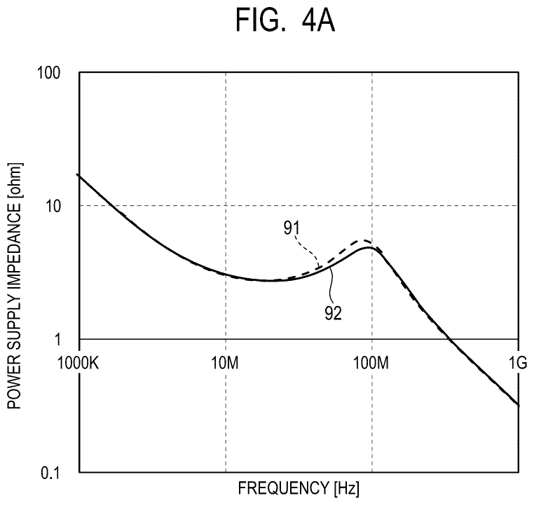

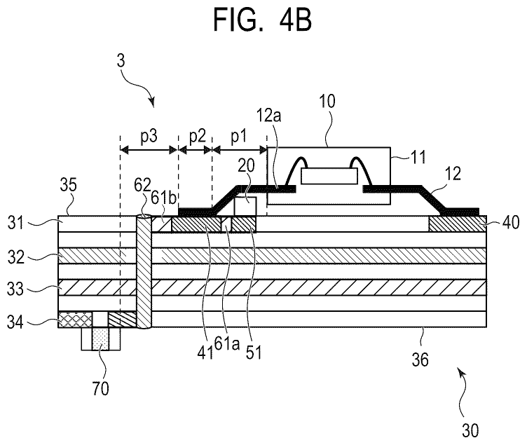

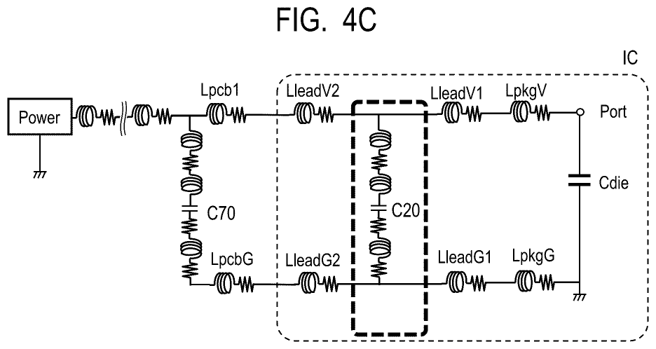

In contrast, the electronic module 3 according to the present embodiment can reduce the power supply impedance without increasing the size. Here, the effects of the configuration according to the present embodiment will be described with reference to FIG. 4A to FIG. 4C.

FIG. 4A is a graph showing simulation results of the power supply impedances inside the integrated circuit devices 10 having the configuration according to the present embodiment illustrated in FIG. 3A to FIG. 3C and the comparative configuration illustrated in FIG. 15A to FIG. 15E. The horizontal axis of the graph indicates the frequency, and the vertical axis indicates the power supply impedance characteristic viewed from the inside of the integrated circuit device 10. In the graph, the solid line 92 indicates the simulation result of the configuration according to the present embodiment, and the dashed line 91 indicates the simulation result of the comparative configuration.

FIG. 4B is a cross-sectional view illustrating a position where the capacitor component according to the present embodiment shown in FIG. 4A is mounted. In the configuration according to the present embodiment, the chip component 20 is mounted between the lead 12a and the lead 12b of the integrated circuit device 10 and the first main surface 35 in the first main surface 35 of the conductor layer 31 on which the integrated circuit device 10 is mounted. In the configuration according to the present embodiment, the chip component 70 is mounted on the second main surface 36 of the conductor layer 34. The chip components 20 and 70 are capacitor components such as multilayer ceramic capacitors or the like, respectively. The chip component 20 is assumed to be a chip component mounted at a position of minimum inductance from the end portion of the semiconductor package. The leads 12a and 12b of the integrated circuit device 10 are connected to the chip component 70, which is a capacitor component, via the component pads, the wirings and the through vias of the printed wiring board 30.

While the chip components 20 and 70 are mounted in the configuration according to the present embodiment, the chip component 20 is not mounted in the comparative configuration, and only the chip component 270 corresponding to the chip component 70 is mounted. The capacitor components constituting the chip components 20, 70 and 270 have the same capacity of 0.01 μF.

FIG. 4C is a circuit diagram illustrating an equivalent circuit from which the power supply impedance shown in FIG. 4A is derived. FIG. 4C models the physical structure illustrated in FIG. 4B in the equivalent circuit. The leads 12a and 12b of the integrated circuit device 10 electrically connect the inside of the semiconductor package to the component pads 41 and 42 provided on the printed wiring board 30. Further, the leads 12a and 12b are electrically connected to the chip components 20 and 70 which are capacitor components via the wirings formed in the printed wiring board 30. These wiring structures are divided into three circuit elements corresponding to distances p1, p2, and p3 indicated in FIG. 4B, respectively.

The portion corresponding to the distance p1 indicated in FIG. 4B is a portion surrounded by air around the leads 12a and 12b from the end of the package body 11 of the semiconductor package of the integrated circuit device 10 to the component pads 41 and 42 provided on the printed circuit board 30. The inductance components of the power supply potential side and the ground potential side of this portion corresponding to the distance p1 are inductance components LleadV1 and LleadG1, respectively.

The portion corresponding to the distance p2 indicated in FIG. 4B is a portion of the leads 12a and 12b that is joined by solder to the component pads 41 and 42 of the printed wiring board 30. The inductance components of the power supply potential side and the ground potential side of this portion corresponding to the distance p2 are inductance components LleadV2 and LleadG2, respectively.

The portion corresponding to the distance p3 indicated in FIG. 4B is a portion of the wiring path from the ends of the component pads 41 and 42 to the chip component 70 mounted on the second main surface 36 of the printed wiring board 30. The inductance components of the power supply potential side and the ground potential side of this portion corresponding to the distance p3 are inductance components Lpcb1 and LpcbG, respectively.

Note that the inductance components of the power supply potential side and the ground potential side of a portion that serves the lead and the wiring path provided inside the semiconductor package of the integrated circuit device 10 are inductance components LpkgV and LpkgG, respectively.

The capacitance component provided inside the integrated circuit device 10 is capacitance component Cdie. The power supply impedance characteristic shown in FIG. 4A is observed at the power supply potential side of the capacitance component Cdie inside the integrated circuit device 10.

In the structure that supplies the power supply potential, the inductance characteristic parasitic on the portion connected from the end portion of the semiconductor package to the chip component 70 mounted on the printed circuit board 30 can be expressed by the following expressions for the comparative configuration and the configuration according to the present embodiment.

$$Comparative configuration : LleadV 1 + LleadV 2 + Lpcb 1$$

Configuration according to the present embodiment: LleadV1

In the structure that supplies the ground potential, the inductance characteristic parasitic on the portion connected from the end of the semiconductor package to the chip component 70 mounted on the printed circuit board 30 can be expressed by the following expressions for the comparative configuration and the configuration according to the present embodiment.

$$Comparative configuration : LleadG 1 + LleadG 2 + Lpcb G$$

Configuration according to the present embodiment: LleadG1

In the integrated circuit device 10, the distance p1 of the portion where the periphery of the leads 12a and 12b is surrounded by air is equal to or less than the distance p2 of the portion of the leads 12a and 12b connected to the component pads 41 and 42 of the printed wiring board 30.

Therefore, in the configuration according to the present embodiment, the inductance component parasitic on the leads 12a and 12b, which is a path connected from the end of the semiconductor package to the chip component 70, is approximately halved as compared with the comparative configuration.

Further, in the configuration according to the present embodiment, the inductance components Lpcb1 and LpcbG parasitic on the portion corresponding to the distance p3 that serves as the wiring path of the printed wiring board 30 are reduced. Therefore, in the configuration according to the present embodiment, the reduction effect of the power supply impedance when the chip component 70, which is a capacitor component, is mounted can be increased. Although the configuration in which the reduction effect of the power supply impedance is particularly remarkable has been described, the chip component 70 may be mounted on the first main surface 35 instead of the second main surface 36. The chip component 70 may be omitted, the chip component 20 may substitute for the chip component 70, and a plurality of the chip components 20 may substitute for the chip component 70.

In the configuration according to the present embodiment, the component pad 41 of the printed circuit board 30 connected to the integrated circuit device 10 is integrated with the component pad 51 on which the chip component 20 is mounted. In addition, in the configuration according to the present embodiment, the component pad 42 of the printed circuit board 30 connected to the integrated circuit device 10 is integrated with the component pad 52 on which the chip component 20 is mounted.

Note that the component pad 41 and the component pad 51 may be separate and independent pads separated from each other, and the component pad 42 and the component pad 52 may be separate and independent pads separated from each other. The component pad 41 and the component pad 51 provided as separate and independent pads may be connected by a wiring provided on the conductor layer 31 of the printed wiring board 30. The component pad 42 and the component pad 52 provided as separate and independent pads may be connected by a wiring formed in the conductor layer 31 as well. With the configuration in which the component pads are connected by wirings, it is unnecessary to make the size of the chip component 20 equal to the pitch of the adjacent leads 12a and 12b, and various mounting structures can be adopted in the electronic module 3. Note that the wiring that connects the component pad 41 and the component pad 51 and the wiring that connects the component pad 42 and the component pad 52 are preferably thick and short in order to reduce the parasitic inductance component.

In addition, in the power supply impedance characteristics shown in FIG. 4A, the configuration of the present embodiment and the comparative configuration are compared under the condition that a capacitor which is the chip component 70 of the same structure and the same capacity is mounted, but the configuration is not limited thereto. By changing the chip component 70 to a component having a larger capacity value, it is possible to increase the frequency band in which the power supply impedance is reduced and the reduction in the power supply impedance.

In addition, the component pad 41 to which the lead 12a to which the power supply potential is supplied is connected and the component pad 42 to which the lead 12b to which the ground potential is supplied is connected may not necessarily be adjacent to each other. In this case, the component size of the chip component 20 can be selected according to the pitch of the leads 12 including the leads 12a and 12b of the integrated circuit device 10.

In addition, the printed wiring board 30 is not limited to a substrate having four layers, but may be a through substrate having two or more through vias. The package structure of the integrated circuit device 10 is not limited to a QFP having terminals on four sides of the package body, but may be a SOP (Small Outline Package) having terminals only on two sides.

In addition, the leads 12, 12a, and 12b of the integrated circuit device 10 and the component pads 40, 41, and 42 are not limited to the case where they are joined by soldering, but may be physically and electrically connected by a conductive material such as a conductive adhesive or the like. The terminals of the chip component 20 and the component pads 51 and 52 are not limited to the case where they are joined by soldering, but may be physically and electrically connected by a conductive material such as a conductive adhesive or the like.

As described above, according to the present embodiment, it is possible to achieve both the reduction of power supply impedance and the miniaturization in the electronic module 3. Thus, according to the present embodiment, an improved mounting structure can be realized, which is effective for the miniaturization of the printed wiring board 30, the improvement of the functionality, and the like.

### Second Embodiment

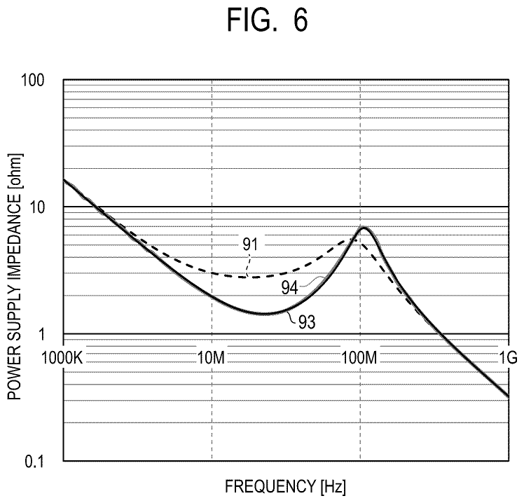

Electronic equipment and an electronic module according to a second embodiment of the present disclosure will be described with reference to FIG. 3B and FIG. 6. The basic configuration of the electronic equipment and the electronic module according to the present embodiment is the same as that of the electronic equipment and the electronic module according to the first embodiment. In the electronic module 3 according to the present embodiment, the chip component 20 mounted on the first main surface 35 of the printed wiring board 30 is soldered and joined to the component pads 51 and 52 provided on the first main surface 35 of the printed wiring board 30 as in the first embodiment.

Further, in the present embodiment, one terminal of the chip component 20 and the lead 12a are soldered and joined even in a region 21 indicated by a dashed ellipse in FIG. 3B where the periphery of the lead 12a of the integrated circuit device 10 is surrounded by air. That is, one terminal of the chip component 20 is soldered and joined to a portion of the lead 12a away from the first main surface 35.

In addition, the other terminal of the chip component 20 and the lead 12b are soldered and joined even in a region corresponding to the region 21 indicated by the dashed ellipse in FIG. 3B where the periphery of the lead 12b is surrounded by air. That is, the other terminal of the chip component 20 is soldered and joined to a portion of the lead 12b away from the first main surface 35.

Note that the terminals of the chip component 20 and the leads 12a and 12b are not limited to the case where they are joined by soldering, but may be physically and electrically connected by a conductive material such as a conductive adhesive or the like.

The method of connecting the terminals of the chip component 20 and the leads 12a and 12b in the region 21 is not particularly limited, but the following method can be exemplified. That is, a method of connecting by printing solder on the portion of the terminals of the chip component 20 facing the leads 12 and joining them by soldering, or a method of connecting by providing a conductor between the chip component 20 and the leads 12 can be exemplified. Another method is, for example, to make a connection using a printed wiring board different from the printed wiring board 30 on the mounting surface opposite the mounting surface that is connected to the printed wiring board 30 of the chip component 20. In this case, a terminal of the chip component 20 is joined to the printed wiring board (not illustrated) by soldering or the like on the opposite mounting surface of the chip component 20, and the printed wiring board (not illustrated) is joined to the leads 12a and 12b by soldering or the like in the region 21.

FIG. 6 is a graph showing simulation result of the power supply impedance in the integrated circuit device 10 of the configuration according to the present embodiment, together with the simulation result of the above-described comparative configuration and the configuration according to the third embodiment described later. The horizontal axis of the graph indicates the frequency, and the vertical axis indicates the power supply impedance characteristic viewed from the inside of the integrated circuit device 10. In the graph, the dashed line 91 indicates the simulation result of the above-described comparative configuration, the solid line 93 indicates the simulation result of the configuration according to the present embodiment, and the solid line 94 indicates the simulation result of the configuration according to the third embodiment.

In the present embodiment, the component pad 41 provided on the first main surface 35 of the printed circuit board 30 on which the integrated circuit device 10 is mounted and the component pad 51 to which the chip component 20 is connected are connected by a wiring 61a having a parasitic inductance of 0.1 nH. The chip component 20 is a multilayer ceramic capacitor of the same component of 0.01 μF as in the case of the comparative configuration and the first embodiment. In the chip component 20, the terminal that supplies the power supply potential and the terminal that supplies the ground potential are respectively connected to the leads 12a and 12b of the integrated circuit device 10 in the region 21. On the other hand, the comparison configuration is the configuration illustrated in FIG. 15A to FIG. 15E described above, and the conditions are the same as those of the simulation shown in FIG. 4A.

The configuration according to the present embodiment is such that the terminal of the chip component 20 and the lead 12a are joined in the region 21, and the terminal of the chip component 20 and the lead 12b are joined in the region corresponding to the region 21. In the configuration according to the present embodiment, in the equivalent circuit illustrated in FIG. 4C, both the inductance component LleadV1 corresponding to the lead 12a to which the power supply potential is supplied and the inductance component LleadG1 corresponding to the lead 12b to which the ground potential is supplied can be reduced compared with the configuration according to the first embodiment.

As a result, in the power supply impedance characteristic shown in FIG. 6, the power supply impedance can be significantly reduced in the configuration according to the present embodiment shown by the solid line 93 compared with the comparison configuration shown by the broken line 91 in the frequency band from 4 MHz to 85 MHz.

Note that the chip component 20 does not necessarily need to have terminals joined to both the leads 12a and 12b as described above. The chip component 20 may only have a terminal connected to at least one of the leads 12a, to which the power supply potential to be supplied to the integrated circuit device 10 is supplied, and the lead 12b, to which the ground potential to be supplied to the integrated circuit device 10 is supplied. However, since both the inductance components LleadV1 and LleadG1 can be reduced as described above, it is preferable that the terminals are connected to both the leads 12a and 12b.

### Third Embodiment

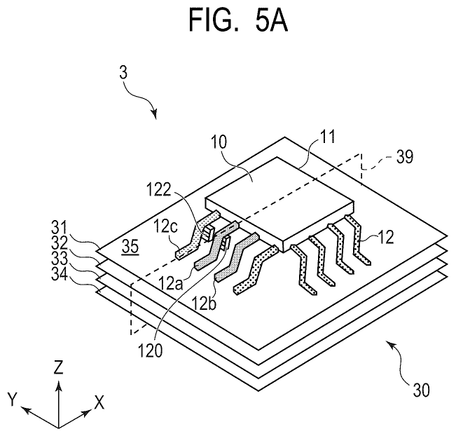

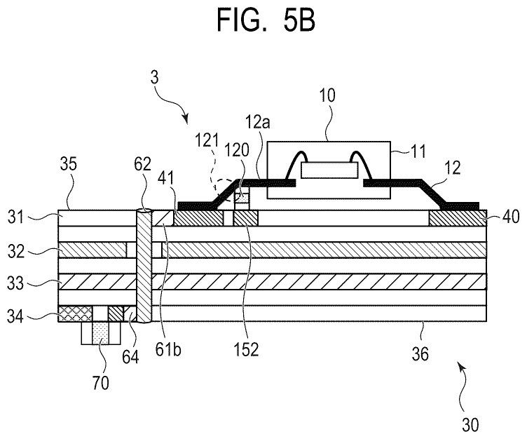

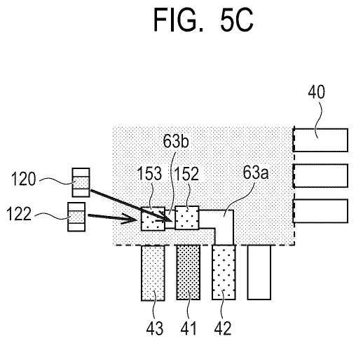

Electronic equipment and an electronic module according to a third embodiment of the present disclosure will be described with reference to FIG. 5A to FIG. 6. The basic configuration of the electronic equipment and the electronic module according to the present embodiment is the same as that of the electronic equipment and the electronic module according to the first embodiment. In the electronic module 3 according to the present embodiment, chip components 120 and 122 are mounted on the printed wiring board 30 instead of the chip component 20.

FIG. 5A is a perspective view illustrating the printed wiring board 30 constituting the electronic module 3 according to the present embodiment. FIG. 5A illustrates a portion of the printed wiring board 30 where the integrated circuit device 10 is mounted.

As illustrated in FIG. 5A, the integrated circuit device 10 and a chip component 120 are mounted on the first main surface 35 of the printed wiring board 30. The chip component 120 is mounted between the lead 12a of the integrated circuit device 10 and the first main surface 35 of the printed wiring board 30. That is, the chip component 120 is arranged between a portion of the lead 12a away from the printed wiring board 30 and the printed wiring board 30. The chip component 120 is a capacitor component such as a multilayer ceramic capacitor or the like.

FIG. 5B is a cross-sectional view illustrating a cross section along the X direction illustrated in a region 39 in FIG. 5A. The cross section illustrated in FIG. 5B includes the lead 12a as a power supply lead which is one of the leads 12 along the X direction to which the power supply potential to be supplied to the integrated circuit device 10 is supplied in the electronic module 3 according to the present embodiment.

As illustrated in FIG. 5B, in the same manner as in the first embodiment, the printed circuit board 30 is a four-layer laminated substrate in which the four conductor layers 31, 32, 33, and 34 are provided at a distance from each other in the Z direction from the first main surface 35 to the second main surface 36. A solder resist (not illustrated) may be arranged on the conductor layers 31 and 34. A conductor pattern constituting wirings is formed in each of the conductor layers 31, 32, 33, and 34. The printed wiring board 30 is provided with the through via 62 which is a through hole constituting a wiring from the conductor layer 31 to the conductor layer 34.

The lead 12a, which is one of the leads 12 of the integrated circuit device 10, is soldered and joined to the component pad 41 provided on the conductor layer 31 of the printed wiring board 30. One terminal of the chip component 120 is soldered and joined to a component pad 152 provided on the conductor layer 31. The other terminal of the chip component 120 is soldered and joined to the lead 12a of the integrated circuit device 10 in a region 121. The region 121 is midway from the end of the package body 11 of the integrated circuit device 10 until the lead 12 is connected to the component pad 41 of the printed circuit board 30. The other terminal of the chip component 120 is soldered and joined to a portion of the lead 12a away from the first main surface 35 in the region 121. The chip component 120 with the two terminals connected is mounted in a direction substantially parallel to the Z direction of the printed wiring board 30.

FIG. 5C is a plan view of the first main surface 35 of the conductor layer 31 of the printed wiring board 30, viewed from the top in the Z direction. As illustrated in FIG. 5C, the component pads 40, 41, 42, and 43 are formed in the conductor layer 31. The component pads 40, 41, 42, and 43 are arranged around the integrated circuit device 10 so as to correspond to the plurality of leads 12.

The plurality of leads 12 of the integrated circuit device 10 are soldered and joined to the component pads 40, 41, 42, and 43. The lead 12a, which is one of the leads 12 to which the power supply potential to be supplied to the integrated circuit device 10 is supplied, is soldered and joined to the component pad 41. The lead 12b, which is one of the leads 12 to which the ground potential to be supplied to the integrated circuit device 10 is supplied, is soldered and joined to the component pad 42.

Further, the component pad 152 and a wiring 63a are formed in the conductor layer 31. The component pad 152 is provided at a position close to or adjacent to the component pad 41 having the power supply potential.

One terminal of the chip component 120 is soldered and joined to the component pad 152. The component pad 152 is electrically connected to the component pad 42 having the ground potential via the wiring 63a. Thus, one terminal of the chip component 120 connected to the component pad 152 is electrically connected to the lead 12b connected to the component pad 42.

Note that the component pads 41 and 42 may be electrically connected to the chip component, such as a capacitor component or the like (not illustrated) mounted in a region other than the region where the integrated circuit device 10 of the first main surface 35 is projected, via wirings (not illustrated) formed in the conductor layer 31. The component pads 41 and 42 are electrically connected to the power supply circuit (not illustrated) that supplies power to the integrated circuit device 10 via wirings (not illustrated) formed in the conductor layer 31.

In the present embodiment, the lead 12a to which the power supply potential to be supplied to the integrated circuit device 10 is supplied can be connected to the other terminal of the chip component 120 before being connected to the component pad 41. Further, one terminal of the chip component 120 can be connected to the lead 12b to which the ground potential is supplied via the component pad 152, the wiring 63a and the component pad 42.

With such a configuration, the distance between the leads 12a and 12b of the integrated circuit device 10 and the chip component 120 can be shortened. Thus, in the present embodiment, the inductance component LleadV1 or LleadG1 shown in FIG. 4C can be reduced. Note that, in order to reduce the inductance component LleadG1, it is preferable that the wiring 63a is thick and short.

In the graph of FIG. 6 described above, the solid line 94 indicates the result of simulating the power supply impedance characteristics of the configuration according to the present embodiment. In the simulation, the inductance component LleadG1 shown in FIG. 4C, which is an inductance component corresponding to the wiring 63a connecting the component pad 42 provided on the first main surface 35 of the printed circuit board 30 to the chip component 120, is set to 0.1 nH. The chip component 120 is a multilayer ceramic capacitor and is made of the same component of 0.01 μF in the same manner as the chip component 20 of the comparative configuration and the first and second embodiments. At this time, the solid line 93 of the configuration according to the second embodiment and the solid line 94 of the configuration according to the present embodiment exhibit substantially the same power supply impedance.

Note that it is preferable that the region 121 where the chip component 120 and the lead 12a are connected is as close as possible to the end of the package body 11 of the integrated circuit device 10. The closer the region 121 is to the end of the package body 11, the greater the effect of reducing the power supply impedance can be.

As illustrated in FIG. 5C, the component pad 43 having a power supply potential different from that of the component pad 41 may be formed in the conductor layer 31 at a position close to or adjacent to the component pad 41 that connects the leads 12a to which the power supply potential to be supplied to the integrated circuit device 10 is supplied. A lead 12c as a power supply lead which is one of the leads 12 of the integrated circuit device 10 is soldered and joined to the component pad 43. Even in such a configuration, by adopting the mounting structure according to the present embodiment, it is possible to reduce both the power supply impedances of the paths for supplying two power supply potentials adjacent to each other.

In order to reduce both the power supply impedances of the two close or adjacent power supply potentials, specifically, a configuration can be employed, in which a chip component 122 is mounted between the lead 12c and the first main surface 35 of the printed circuit board 30 as follows. That is, the chip component 122 may be arranged between a portion of the lead 12c away from the printed circuit board 30 and the printed circuit board 30.

Specifically, as illustrated in FIG. 5C, a component pad 153 having a ground potential is formed in the conductor layer 31 at a position close to or adjacent to the component pad 43. The component pad 153 is electrically connected to the component pad 152 via a wiring 63b formed in the conductor layer 31. The component pad 152 is electrically connected to the component pad 42 via the wiring 63a. One terminal of the chip component 122 is soldered and joined to the component pad 153. The one terminal of the chip component 122 joined to the component pad 153 is electrically connected to the lead 12b joined to the component pad 42 via the wiring 63b, the component pad 152, and the wiring 63a. The other terminal of the chip component 122 is soldered and joined in a region corresponding to the region 121 of the lead 12c connected to the component pad 43. That is, the other terminal of the chip component 122 is soldered and joined to a portion of the lead 12c away from the first main surface 35 in the region corresponding to the region 121. The chip component 122 with the two terminals connected as such is mounted in a direction substantially parallel to the Z direction of the printed wiring board 30. The chip component 122 is a capacitor component such as a multilayer ceramic capacitor or the like.

The component pad 41 that supplies another power supply potential is interposed between the component pad 43 that supplies the power supply potential and the component pad 42 that supplies the ground potential. In this way, the component pad 43 that supplies the power supply potential and the component pad 42 that supplies the ground potential may be separated. In this case, the integrated circuit device 10 and the chip component 122 can be electrically connected with low impedance by mounting the chip component 122 in a direction substantially parallel to the Z direction of the printed circuit board 30.

Note that, although the structure of joining the leads 12a and 12c of the integrated circuit device 10 having the power supply potentials with the chip components 120 and 122 has been described, the embodiment is not limited thereto. One terminal of the chip component 120 may be soldered and joined to the lead 12 having a ground potential. In this case, the other terminal of the chip component 120 may be soldered and joined to a component pad having a power supply potential provided on the conductor layer 31 of the printed wiring board 30. One terminal of the chip component 122 may also be soldered to and joined to the lead 12 having a ground potential. In this case, the other terminal of the chip component 122 may be soldered to and joined to a component pad having a power supply potential provided on the conductor layer 31 of the printed wiring board 30.

Note that a portion of the package body 11 of the integrated circuit device 10 may be located at a position lower than the heights of the chip components 120 and 122. Even in this case, spaces for mounting the chip components 120 and 122 can be secured between the first main surface 35 of the printed circuit board 30 and the leads 12.

Further, the leads 12, 12a, and 12c of the integrated circuit device 10 and the terminals of the chip components 120 and 122 are not limited to the case where they are joined by soldering, but may be physically and electrically connected by a conductive material such as a conductive adhesive or the like. Further, the terminals of the chip components 120 and 122 and the component pads 152, 153 are not limited to the case where they are joined by soldering, but may be physically and electrically connected by a conductive material such as a conductive adhesive or the like.

As described above, according to the present embodiment, it is possible to achieve both the reduction of power supply impedance and the miniaturization in the electronic module 3.

### Fourth Embodiment

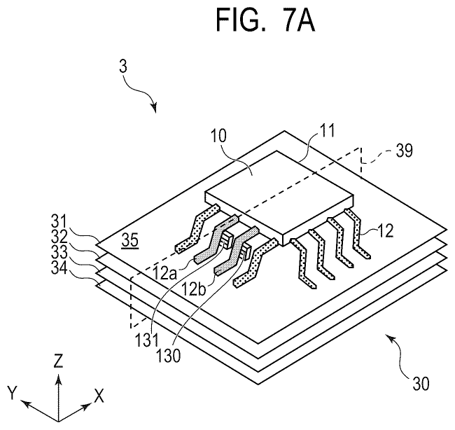

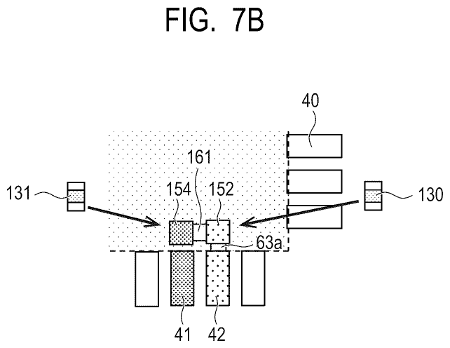

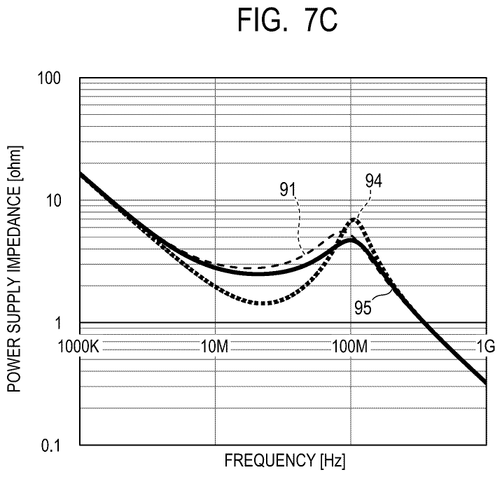

Electronic equipment and an electronic module according to a fourth embodiment of the present disclosure will be described with reference to FIG. 7A to FIG. 7C. The basic configuration of the electronic equipment and the electronic module according to the present embodiment is the same as that of the electronic equipment and the electronic module according to the first embodiment. In the electronic module 3 according to the present embodiment, chip components 130 and 131 are mounted on the printed wiring board 30 instead of the chip component 20.

FIG. 7A is a perspective view illustrating the printed wiring board 30 constituting the electronic module 3 according to the present embodiment. FIG. 7A illustrates a portion of the printed wiring board 30 where the integrated circuit device 10 is mounted.

As illustrated in FIG. 7A, the integrated circuit device 10 and chip components 130 and 131 are mounted on the first main surface 35 of the printed wiring board 30. Similar to the third embodiment illustrated in FIG. 5A, the chip component 131 is mounted between the lead 12a of the integrated circuit device 10 and the first main surface 35 of the printed circuit board 30. The chip component 130 is mounted between the lead 12b of the integrated circuit device 10 and the first main surface 35 of the printed circuit board 30. The chip component 131 is a resistance component, and the chip component 130 is a capacitor component such as a multilayer ceramic capacitor or the like.

The chip component 131 is mounted between the lead 12a having the power supply potential and the first main surface 35 of the printed wiring board 30. That is, the chip component 131 is arranged between a portion of the lead 12a away from the printed wiring board 30 and the printed wiring board 30. The chip component 130 is mounted between the lead 12b having the ground potential and the first main surface 35 of the printed wiring board 30. That is, the chip component 130 is arranged between a portion of the lead 12b away from the printed wiring board 30 and the printed wiring board 30.

FIG. 7B is a plan view of the first main surface 35 of the printed wiring board 30 viewed from the top the Z direction. As illustrated in FIG. 7B, the component pads 40, 41, and 42 are formed in the conductor layer 31. The component pads 40, 41, and 42 are arranged side by side around the integrated circuit device 10 so as to correspond to the plurality of leads 12.

The plurality of leads 12 of the integrated circuit device 10 are soldered and joined to the component pads 40, 41, and 42. The lead 12a, which is one of the leads 12 supplied with the power supply potential to be supplied to the integrated circuit device 10, is soldered and joined to the component pad 41. The lead 12b, which is one of the leads 12 supplied with the ground potential to be supplied to the integrated circuit device 10, is soldered and joined to the component pad 42.

Further, the component pads 152 and 154 and the wirings 63a and 161 are formed in the conductor layer 31. The component pad 152 is provided at a position close to or adjacent to the component pad 42 having the ground potential. The component pad 154 is provided at a position close to or adjacent to the component pad 41 having the power supply potential.

One terminal of the chip component 131 is soldered and joined to the component pad 154. The other terminal of the chip component 131 is soldered and joined to the middle of the lead 12a having the power supply potential. That is, the other terminal of the chip component 131 is soldered and joined to a portion of the lead 12a away from the first main surface 35.

One terminal of the chip component 130 is soldered and joined to the component pad 152. The other terminal of the chip component 130 is soldered and joined to the middle of the lead 12b having the ground potential. That is, the other terminal of the chip component 130 is soldered and joined to a portion of the lead 12b away from the first main surface 35.

The component pad 152 is electrically connected to the component pad 42 having the ground potential via the wiring 63a. The component pad 154 is electrically connected to the component pad 152 via the wiring 161. The one terminal of the chip component 130 connected to the component pad 152 is electrically connected to the lead 12b connected to the component pad 42, via the wiring 63a. The one terminal of the chip component 131 connected to the component pad 154 is electrically connected to the lead 12b connected to the component pad 42, via the wiring 161, the component pad 152, and the wiring 63a.

With such a configuration, the resistor and the capacitor can be connected in series between the power supply potential and the ground potential of the integrated circuit device 10. Note that the chip component 131 may be a capacitor component and the chip component 130 may be a resistor component.

Note that the component pads 41 and 42 are electrically connected to a power supply circuit (not illustrated) via wirings (not illustrated) formed in the conductor layer 31 in a region other than the region where the integrated circuit device 10 of the first main surface 35 is projected. A filter component represented by a ferrite bead may be connected between the component pads 41 and 42 and the power supply circuit (not illustrated).

FIG. 7C is a graph showing simulation results of the power supply impedance characteristics in the integrated circuit device 10 according to the configuration according to the above-described comparative configuration, the configuration according to the third embodiment, and the configuration according to the present embodiment. The horizontal axis of the graph indicates the frequency, and the vertical axis indicates the power supply impedance characteristics viewed from the inside of the integrated circuit device 10. In the graph, the dashed line 91 indicates the simulation result of the comparative configuration, the solid line 94 indicates the simulation result of the configuration according to the third embodiment, and the solid line 95 indicates the simulation result of the configuration according to the present embodiment.

The chip component 130 is a multilayer ceramic capacitor, and is the same component of 0.01 μF as in the case of the comparative configuration and the third embodiment. The chip component 131 is a chip resistance component of 1.1 Ω. The wirings 63a and 161 each have a parasitic inductance of 0.1 nH.

With such a configuration, according to the present invention, the power supply impedance increased in the 100 MHz band in the configuration according to the third embodiment can also be reduced.

Note that a portion of the package body 11 of the integrated circuit device 10 may be located at a position lower than the heights of the chip components 130 and 131. Even in this case, spaces for mounting the chip components 130 and 131 can be secured between the first main surface 35 of the printed circuit board 30 and the leads 12.

Further, the leads 12a and 12b of the integrated circuit device 10 and the terminals of the chip components 131 and 130 are not limited to the case where they are joined by soldering, but may be physically and electrically connected by a conductive material such as a conductive adhesive or the like. Further, the terminals of the chip components 131 and 130 and the component pads 154 and 152 are not limited to the case where they are joined by soldering, but may be physically and electrically connected by a conductive material such as a conductive adhesive or the like.

As described above, according to the present embodiment, it is possible to achieve both the reduction of power supply impedance and the miniaturization in the electronic module 3.

### Fifth Embodiment

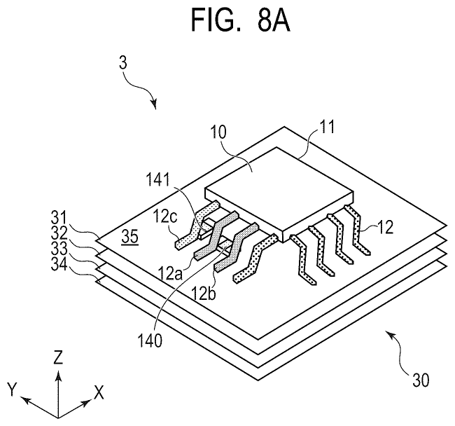

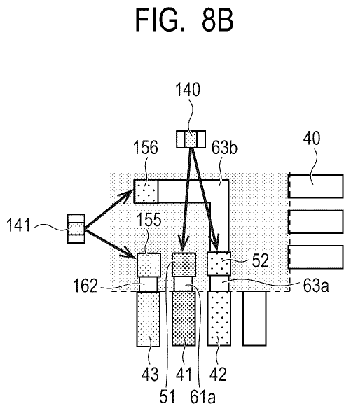

Electronic equipment and an electronic module according to a fifth embodiment of the present disclosure will be described with reference to FIG. 8A and FIG. 8B. The basic configuration of the electronic equipment and the electronic module according to the present embodiment is the same as that of the electronic equipment and the electronic module according to the first embodiment. In the electronic module 3 according to the present embodiment, chip components 140 and 141 are mounted on the printed wiring board 30 instead of the chip component 20.

FIG. 8A is a perspective view illustrating the printed wiring board 30 constituting the electronic module 3 according to the present embodiment. FIG. 8A illustrates a portion of the printed wiring board 30 where the integrated circuit device 10 is mounted.

As illustrated in FIG. 8A, the integrated circuit device 10 and chip components 140 and 141 are mounted on the first main surface 35 of the printed wiring board 30. The chip component 140 is mounted between the leads 12a and 12b of the integrated circuit device 10 and the first main surface 35 of the printed wiring board 30. That is, the chip component 140 is arranged between portions of the leads 12a and 12b away from the printed wiring board 30 and the printed wiring board 30. The chip component 141 is mounted between the lead 12c of the integrated circuit device 10 and the first main surface 35 of the printed wiring board 30. That is, the chip component 141 is arranged between a portion of the lead 12c away from the printed wiring board 30 and the printed wiring board 30. The chip components 140 and 141 are capacitor components such as multilayer ceramic capacitors or the like.

FIG. 8B is a plan view of the first main surface 35 of the conductor layer 31 of the printed wiring board 30, viewed from the top in the Z direction. As illustrated in FIG. 8B, the component pads 40, 41, 42, and 43 are formed in the conductor layer 31. The component pads 40, 41, 42, and 43 are arranged around the integrated circuit device 10 so as to correspond to the plurality of leads 12.

The plurality of leads 12 of the integrated circuit device 10 are soldered and joined to the component pads 40, 41, 42, and 43. The lead 12a, which is one of the leads 12 to which the power supply potential to be supplied to the integrated circuit device 10 is supplied, is soldered and joined to the component pad 41. The lead 12b, which is one of the leads 12 to which the ground potential is supplied to the integrated circuit device 10, is soldered and joined to the component pad 42. The lead 12c, which is one of the leads 12 to which the power supply potential to be supplied to the integrated circuit device 10 is supplied, is soldered and joined to the component pad 43. The power supply potential different from the power supply potential supplied to the lead 12a is supplied to the lead 12c.

The component pads 51 and 52 and the wirings 61a, 63a, and 63b are formed in the conductor layer 31. The component pad 51 is provided at a position close to or adjacent to the component pad 41 having the power supply potential. The component pad 52 is provided at a position close to or adjacent to the component pad 42 having the ground potential.

One terminal of the chip component 140 is soldered and joined to the component pad 51. The other terminal of the chip component 140 is soldered and joined to the component pad 52. The component pad 51 is electrically connected to the component pad 41 via the wiring 61a. The component pad 52 is electrically connected to the component pad 42 via the wiring 63a. The one terminal of the chip component 140 connected to the component pad 51 is electrically connected to the lead 12a connected to the component pad 41, via the wiring 61a. The other terminal of the chip component 140 connected to the component pad 52 is electrically connected to the lead 12b connected to the component pad 42, via the wiring 63a.

One terminal of the chip component 141 is soldered and joined to the component pad 155. The component pad 155 is electrically connected via the wiring 162 to the component pad 43 to which the lead 12c, which is one of the leads 12 of the integrated circuit device 10, is connected. The other terminal of the chip component 141 is soldered and joined to the component pad 156. The component pad 156 is electrically connected to the component pad 52 to which the other terminal of the chip component 140 is connected, via the wiring 63b. The component pad 52 is soldered and joined to the component pad 42 to which the lead 12b, which is one of the leads 12 of the integrated circuit device 10, is connected, via the wiring 63a. The one terminal of the chip component 141 joined to the component pad 155 is electrically connected to the lead 12c joined to the component pad 43, via the wiring 162. The other terminal of the chip component 141 joined to the component pad 156 is electrically connected to the lead 12b joined to the component pad 42, via the wiring 63b, the component pad 52, and the wiring 63a.

The component pads 41, 42, and 43 are connected to the chip component (not illustrated) provided on the conductor layer 31 or the conductor layer 34 of the printed wiring board 30 via wirings (not illustrated) formed in the conductor layer 31. The component pads 41, 42, and 43 are electrically connected to the power supply circuit (not illustrated) via wirings (not illustrated) formed in the conductor layer 31.

Note that, in FIG. 8A and FIG. 8B, the chip component 140 and the chip component 141 differ from each other in terms of the component size and the mounted orientation, but it is not necessary that the component size and mounted orientation differ from each other.

In the present embodiment, the component sizes and the mounted orientation of the chip components 140 and 141 mounted between the leads 12a, 12b, and 12c and the first main surface 35 of the integrated circuit device 10, the wiring structures for connecting the chip components 140 and 141, and the like can be adjusted. Thus, in the present embodiment, the inductance parasitic on the path for supplying the power supply potential to the integrated circuit device 10 can be reduced, and the power supply impedance can be reduced.

The one terminal and the other terminal of the chip component 140 are preferably soldered and joined to middles of the leads 12a and 12b of the integrated circuit device 10, respectively, as described in the second to fourth embodiments. The one terminal or the other terminal of the chip component 141 are preferably soldered and joined to a middle of the leads 12c of the integrated circuit device 10, respectively, as described in the second to fourth embodiments.

The two terminals of the chip component 140 are joined to the component pads 51 and 52, but are not limited thereto. Of the two terminals of the chip component 140, one terminal may be joined to the component pad 51, the other terminal may be joined to a middle of the lead 12b, or one terminal may be joined to a middle of the lead 12a, and the other terminal may be joined to the component pad 52.

Note that a portion of the package body 11 of the integrated circuit device 10 may be located at a position lower than the heights of the chip components 140 and 141. Even in this case, spaces for mounting the chip components 140 and 141 can be secured between the first main surface 35 of the printed circuit board 30 and the leads 12.

The terminals of the chip components 140 and 141 and the component pads 51, 52, 155, and 156 are not limited to the case where they are joined by soldering, but may be physically and electrically connected by a conductive material such as a conductive adhesive or the like. Further, the leads 12a, 12b, and 12c of the integrated circuit device 10 and the terminals of the chip components 131, 130 are not limited to the case where they are joined by soldering, but may be physically and electrically connected by a conductive material such as a conductive adhesive or the like.

As described above, according to the present embodiment, it is possible to achieve both the reduction of power supply impedance and the miniaturization in the electronic module 3.

### Other Embodiments

The present disclosure is not limited to the embodiments described above and can be modified in a variety of ways. For example, the embodiments of the present disclosure also include an example in which a part of a configuration of one embodiment is added to another embodiment, and an example in which a part of a configuration of one embodiment is substituted with a part of a configuration of another embodiment.

Although the above embodiments have been described with examples in which the integrated circuit device 10 is mounted as a semiconductor component, other semiconductor components may be mounted in place of the integrated circuit device 10.

In addition, the power supply potential and the ground potential supplied to respective parts of the leads 12a and 12b, the component pads 41 and 42, and the like in the electronic module 3 may be opposite to those in the above-described embodiments.

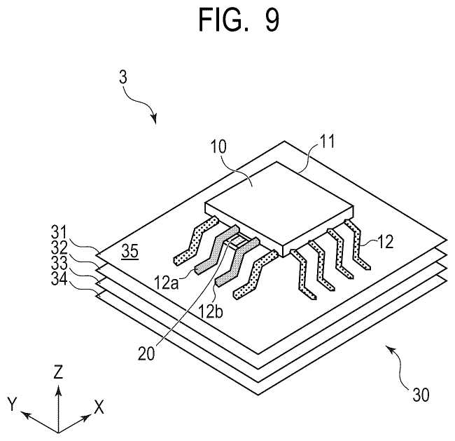

In addition, the chip components 20 may be soldered and joined to the leads 12a and 12b. For example, as illustrated in FIG. 9, one terminal of the chip components 20 may be soldered and joined to the lead 12a, and the other terminal of the chip components 20 may be soldered and joined to the leads 12b. Thus, the chip components 20 may be soldered to the leads 12a and 12b and mounted between the main surface 35 of the printed wiring board 30 and the leads 12a and 12b.

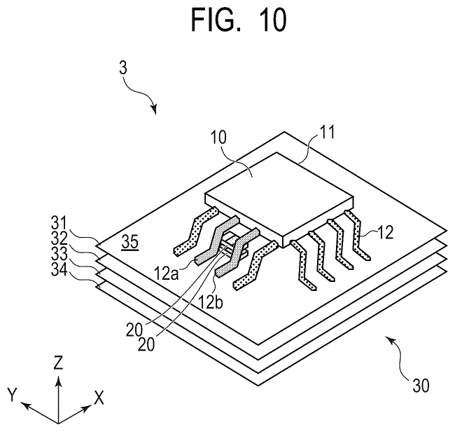

In addition, the chip components 20 may be stacked on the main surface 35 of the printed wiring board 30. For example, as illustrated in FIG. 10, a plurality of the chip components 20 may be stacked and mounted vertically on the printed wiring board 30 between the main surface 35 of the printed wiring board 30 and the leads 12a and 12b. In this case, one terminal of the lower chip component 20 is connected to the component pad 51. The other terminal of the lower chip component 20 is connected to the component pad 52. One terminal of the upper chip component 20 is connected to the one terminal of the lower chip component 20. The other terminal of the upper chip component 20 is connected to the other terminal of the lower chip component 20.

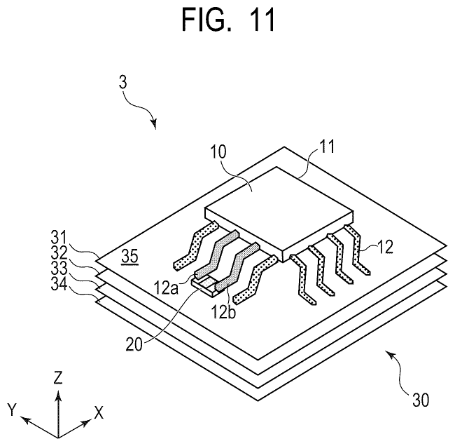

In addition, the chip component 20 may be mounted on the main surface 35 of the printed wiring board 30 by connecting the terminals to the component pads 41 and 42 to which the leads 12a and 12b are connected. For example, as illustrated in FIG. 11, the leads 12a and 12b may be connected to the printed wiring board 30 via the chip component 20 mounted on the main surface 35 of the printed wiring board 30. In this case, the leads 12a are electrically connected to the component pad 41 via one terminal of the chip component 20. The leads 12b are electrically connected to the component pad 42 via the other terminal of the chip component 20. The one terminal and the other terminal of the chip component 20 are soldered and joined to the component pads 41 and 42, respectively. Thus, the leads 12a and 12b may be electrically connected to the component pads 41 and 42 via the one terminal and the other terminal of the chip component, respectively.

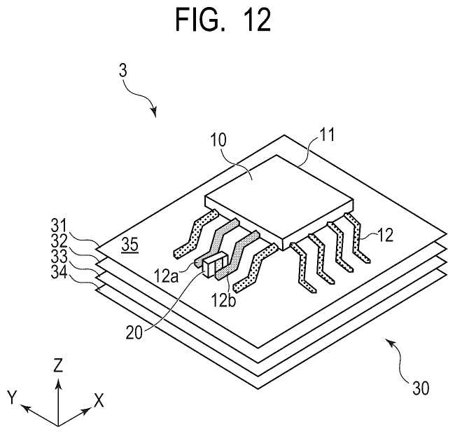

In addition, the chip component 20 may also be mounted on the printed wiring board 30 so as to be positioned between two adjacent leads 12. For example, as illustrated in FIG. 12, the chip component 20 may be mounted on the main surface 35 of the printed wiring board 30 so as to be positioned between the leads 12a and 12b. The chip component 20 is arranged so as not to overlap the package body 11 in a direction perpendicular to the main surface of the printed wiring board 30.

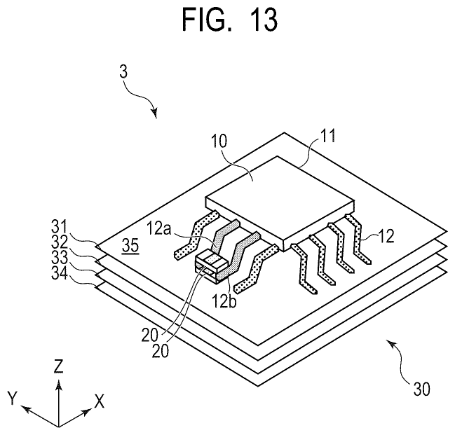

In addition, the chip component 20 can also be mounted on the leads 12. For example, as illustrated in FIG. 13, the chip component 20 may be mounted on the leads 12a and 12b connected to the printed wiring board 30 via the chip component 20 illustrated in FIG. 11. In this case, one terminal of the chip component 20 mounted on the leads 12a and 12b is connected to the lead 12a. The other terminal of the chip component 20 is connected to the lead 12b. The chip component 20 is soldered to the leads 12a and 12b so as not to overlap the package body 11 in a direction perpendicular to the main surface of the printed wiring board 30.

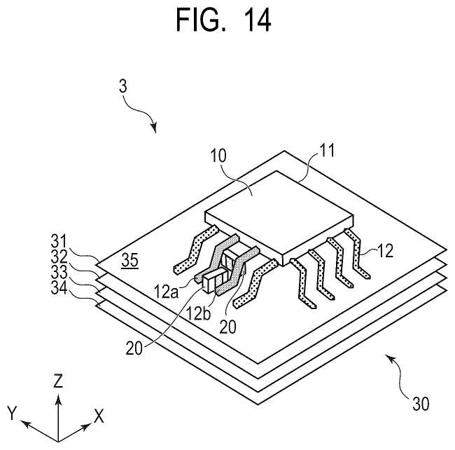

In addition, the chip component 20 illustrated in FIG. 12 mounted on the printed circuit board 30 so as to be arranged between two adjacent leads 12 can also be mounted on the printed circuit board 30 together with other chip components 20. For example, as illustrated in FIG. 14, in addition to the chip component 20 mounted on the first main surface 35 of the printed circuit board 30 as described in the first embodiment, the chip component 20 may be mounted on the first main surface 35 so as to be arranged between the leads 12a and 12b.

In addition, in the above-described embodiments, the cases in which the chip components 20, 70, 120, 122, 130, 140, and 141 are capacitor components are described as examples, but are not limited thereto. The chip components 20, 70, 120, 122, 130, 140, and 141 may be resistor components, inductor components, diode components, or the like, in addition to capacitor components. In this case, the leads 12a, 12b, and 12c may be signal leads into which signals are input or output, as well as power supply leads or ground leads. Chip components, such as capacitor components, resistor components, inductor components, diode components, and the like, may be arranged under the signal leads in the same manner as described above.

In addition, a second portion soldered to a first portion may be further soldered to a third portion different from the first portion. Here, the first portion, the second portion, and the third portion are any of terminals, leads, and pads. For example, a terminal soldered to a lead may also be soldered to a pad.

Note that the above-described embodiments are mere examples of embodiment for implementing the present disclosure, and the technical scope of the present disclosure should not be interpreted to be limited by these examples. That is, the present disclosure may be implemented in various forms without departing from the technical concept or its main features.

According to the present disclosure, an advantageous technique for realizing an improved mounting structure in an electronic module can be provided.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-117857, filed Jul. 23, 2024, which is hereby incorporated by reference herein in its entirety.

What is claimed is:

1. An electronic module comprising:
a printed wiring board;
a semiconductor component mounted on the printed wiring board and having a first lead and a second lead soldered to the printed wiring board, respectively; and
a chip component,
wherein the chip component is arranged between the printed wiring board and at least one of the first lead and the second lead, and
wherein a portion of a package body of the semiconductor component is lower than a height of the chip component.

2. The electronic module according to claim 1, wherein the chip component is arranged so that the chip component does not overlap the package body of the semiconductor component in a direction perpendicular to a main surface of the printed wiring board.

3. An electronic module comprising:
a printed wiring board;
a semiconductor component mounted on the printed wiring board and having a first lead and a second lead soldered to the printed wiring board, respectively; and
a chip component,
wherein the chip component is arranged between the first lead and the second lead so that the chip component does not overlap a package body of the semiconductor component in a direction perpendicular to a main surface of the printed wiring board.

4. An electronic module comprising:
a printed wiring board;
a semiconductor component mounted on the printed wiring board and having a first lead and a second lead soldered to the printed wiring board, respectively; and
a chip component,
wherein the chip component is soldered to the first lead and the second lead so that the chip component does not overlap a package body of the semiconductor component in a direction perpendicular to a main surface of the printed wiring board.

5. The electronic module according to claim 1, wherein the chip component has a first terminal and a second terminal, and
wherein the first terminal is electrically connected to the first lead.

6. The electronic module according to claim 5, wherein the second terminal is electrically connected to the second lead.

7. The electronic module according to claim 5, wherein the first terminal is soldered to the first lead.

8. The electronic module according to claim 7, wherein the second terminal is soldered to the second lead.

9. The electronic module according to claim 5, wherein the first terminal is soldered to the printed wiring board.

10. The electronic module according to claim 9, wherein the second terminal is soldered to the second lead.

11. The electronic module according to claim 9, wherein the printed wiring board has a first pad to which the first terminal is soldered, and
wherein the first pad is electrically connected to the first lead.

12. The electronic module according to claim 9, wherein the second terminal is soldered to the printed wiring board.

13. The electronic module according to claim 12, wherein the printed wiring board has a first pad to which the first terminal is soldered, and
wherein the first pad is electrically connected to the first lead.

14. The electronic module according to claim 12, wherein the printed wiring board has a second pad to which the second terminal is soldered, and
wherein the second pad is electrically connected to the second lead.

15. The electronic module according to claim 1, wherein the chip component includes a plurality of chip components, which are stacked.

16. The electronic module according to claim 1, wherein the first lead is connected to the printed wiring board via the chip component.

17. The electronic module according to claim 1, comprising another chip component mounted on the first lead.

18. The electronic module according to claim 1, wherein the first lead and the second lead are adjacent to each other,
the electronic module comprising another chip located between the first lead and the second lead.

19. The electronic module according to claim 1, wherein the chip component is a capacitor component.

20. Electronic equipment comprising:
a housing; and
the electronic module according to claim 1 arranged inside the housing.
